(19) United States
(12) Patent Application Publication
(10) Pub. No.: US 2025/0349783 A1
(43) Pub. Date: Nov. 13, 2025

(54) FAN-OUT WAFER-LEVEL PACKAGING UNIT

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 19/201,945

(22) Filed: May 8, 2025

(30) Foreign Application Priority Data
May 13, 2024 (TW) 113117553

(51) Int. Cl. H01L 23/00; H01L 21/48; H01L 21/56; H01L 23/31; H01L 23/498; H01L 23/538; H01L 25/065

(52) U.S. Cl. CPC H01L 24/24; H01L 21/4853; H01L 21/56; H01L 23/3135; H01L 23/49816; H01L 23/5385; H01L 23/5386; H01L 24/19; H01L 24/20; H01L 24/32; H01L 24/73; H01L 25/0655; H01L 2224/19; H01L 2224/215; H01L 2224/24137; H01L 2224/24226; H01L 2224/244; H01L 2224/32225; H01L 2224/73267; H01L 2924/15174

(57) ABSTRACT

A fan-out wafer-level packaging (FOWLP) is provided. The FOWLP unit includes a substrate, at least two dies, a first dielectric layer, a second dielectric layer, a plurality of conductive circuits, at least two first bonding pads, at least one first bonding wire, and an outer protective layer. The dies are electrically connected to each other by the first bonding wire. The respective conductive circuits are formed by a metal paste filled in first slots of the first dielectric layer and second slots of the second dielectric layer. A second bonding pad is formed in respective openings of the outer protective layer. The die is electrically connected to the outside by the second bonding pad around a chip area above the second surface of the die. Thereby problems of conventional FOWLP generated during manufacturing of conductive circuits including higher manufacturing cost and less environmental benefits are solved.

### CROSS-REFERENCE TO RELATED APPLICATIONS

This non-provisional application claims priority under 35 U.S.C. § 119 (a) on Patent Application No(s). 113117553 filed in Taiwan, R.O.C. on May 13, 2024, the entire contents of which are hereby incorporated by reference.

### BACKGROUND OF THE INVENTION

The present invention relates to a packaging unit, especially to a fan-out wafer level packaging (FOWLP) unit.

Packaging technology with features of compact design, high efficiency and reliability is a trend in semiconductor industry. In the semiconductor packaging, Fan-Out Wafer Level Packaging (FOWLP) is a packaging technology available now.

In the advanced packaging process such as FOWLP, a redistribution layer (RDL) is the most critical because respective conductive circuits in the RDL make a plurality of die pads on dies have electrical extension in the XY plane and interconnections. Thus a plurality of bonding pads is arranged around the die in a more distributed manner. Thereby design, space, and reliability of the respective conductive circuits are effectively improved. Yet how to keep balance between the electrical extension in the XY plane and interconnections of the conductive circuits and the compact design to a certain degree. The most critical point is the manufacturing of the respective conductive circuits in the RDL. However, the formation of the respective conductive circuits in the RDL of the FOWLP technology available now is by chemical plating or electroplating. Thus not only cost for material and manufacturing is high, the manufacturing process is also not environmental friendly.

Moreover, in order to provide products with higher performance or more functions, at least two dies are disposed in FOWLP unit and the multi-die type FOWLP unit is integrated by RDL. At the moment, space requirement for designing the conductive circuits in the RDL of the FOWLP unit is increased and manufacturing of the conductive circuits in the RDL is more crucial. In the multi-die type FOWLP unit available now, and there is no effective electrical connection between the at least two dies.

### SUMMARY OF THE INVENTION

Therefore, it is a primary object of the present invention to provide a fan-out wafer-level packaging (FOWLP) unit which includes a substrate, at least two dies, a first dielectric layer, a second dielectric layer, a plurality of conductive circuits, at least two first bonding pads, at least one first bonding wire, and an outer protective layer. The dies are electrically connected to each other by the first bonding wire. The respective conductive circuits are formed by a metal paste filled in a plurality of first slots of the first dielectric layer and a plurality of second slots of the second dielectric layer. A second bonding pad is formed in respective openings of the outer protective layer. The die is electrically connected to the outside by the second bonding pad around a chip area above the second surface of the die. Thereby problems of the FOWLP technology available now generated during manufacturing of the respective conductive circuits including higher manufacturing cost and less environmental benefits can be solved.

In order to achieve the above object, a FOWLP unit according to the present invention includes a substrate, at least two dies, a first dielectric layer, a second dielectric layer, a plurality of conductive circuits, at least two first bonding pads, at least one first bonding wire, and an outer protective layer. The dies are cut from the same wafer or different wafers and provided with a first surface and a second surface opposite to each other. The dies are arranged at the substrate in parallel and spaced apart from each other. The first surface of the die is fixed on the substrate while the second surface of the die is provided with a plurality of die pads. An area just above the second surface of the die is defined as a chip area. The first dielectric layer is mounted to the substrate and the second surface of the dies and provided with a plurality of first slots extending in a horizontal direction. The respective die pads of the dies are exposed through the respective first slots. The second dielectric layer is disposed over the first dielectric layer and provided with a plurality of second slots extending in a horizontal direction. The respective second slots are communicating with the respective first slots. The conductive circuits are formed by a metal paste filled in the first slots and the second slots. The respective conductive circuits are electrically connected with the respective die pads of the respective dies. The first bonding pads are arranged in a manner that the two first bonding pads are disposed on the two conductive circuits of the die correspondingly. The first bonding wire forms a first bonding point and a second bonding point on the two first bonding pads correspondingly of the respective dies by a wire bonding process. Thus the dies are electrically connected through the first bonding wire. The outer protective layer is arranged over the second dielectric layer and covering the first bonding pads and the first bonding wire. The outer protective layer is provided with a plurality of openings and at least two of the openings are located around the chip area on the second surface of the respective dies. Each of the conductive circuits is exposed through the corresponding opening and forming a second bonding pad in the opening. The dies are electrically connected to the outside through the die pads, the conductive circuits, and the second bonding pads in turn. Thereby the FOWLP unit is formed. The dies in the FOWLP are electrically connected through the first bonding wire. A method of manufacturing the FOWLP unit includes the following steps. Step S1: providing a substrate. Step S2: arranging a plurality of dies cut from the same wafer or different wafers on the substrate in parallel and spaced from one another. Each of the dies includes a first surface and a second surface opposite to the first surface. The first surface of the die is arranged at the substrate while the second surface of the die is provided with a plurality of die pads. An area just above the second surface is defined as a chip area. Step S3: paving a first dielectric layer over the substrate and the second surface of the respective dies. Step S4: forming a plurality of first slots extending horizontally on the first dielectric layer and exposing the respective die pads of the respective dies through the respective first slots. Step S5: arranging a second dielectric layer over the first dielectric layer. Step S6: forming a plurality of second slots extending horizontally on the second dielectric layer and communicating the second slots with the first slots correspondingly. Step S7: filling a metal paste into the respective first slots and the respective second slots and allowing a level of the metal paste higher than a surface of the second dielectric layer. Step S8: grinding the metal paste with the level higher than the surface of the second dielectric layer to make a surface of the metal paste flush with the surface of the second dielectric layer and form a plurality of conductive circuits. Step S9: forming a first bonding pad on the respective conductive circuits in the respective dies and arranging the first bonding pads in a manner that the two first bonding pads are disposed on the conductive circuits corresponding to each other. Step S10: performing wire bonding for allowing at least one first bonding wire to form a first bonding point and a second bonding point on the first bonding pads of the dies correspondingly.

The dies are electrically connected by the first bonding wire. Step S11: covering the second dielectric layer with an outer protective layer which covers the first bonding pads and the first bonding wire. Step S12: forming a plurality of openings on the outer protective layer and at least one of the openings is formed around the chip area on the second surface of the respective dies so that each of the respective conductive circuits is exposed through the corresponding opening to form a second bonding pad in the opening. Step S13: performing cutting to form a plurality of fan-out wafer-level packaging (FOWLP) units each of which having at least the two dies packaged therein.

Preferably, the die can be electrically connected to the first bonding pad of another die through the die pad, the conductive circuit, and the first bonding wire on the corresponding first bonding pad in turn.

Preferably, the dies are cut from the same wafer or different wafers.

Preferably, levels of the second surfaces of the respective dies on the substrate are the same.

Preferably, the substrate includes silicon substrate, glass substrate, and ceramic substrate.

Preferably, the metal paste includes silver paste, nano-scale silver paste, copper paste, and nano-scale copper paste.

Preferably, the first surface of the die is disposed on the substrate by a die attach film (DAF).

Preferably, each of the openings is provided with a solder ball which is electrically connected to the second bonding pad in the opening.

Preferably, the FOWLP unit is electrically connected to and disposed on an electronic component by the solder balls.

### BRIEF DESCRIPTION OF THE DRAWINGS

FIG. 1 is a side sectional view showing a fan-out wafer level packaging unit disposed on a printed circuit board of an embodiment according to the present invention;

FIG. 2 is a side sectional view showing dies arranged at a substrate of an embodiment according to the present invention;

FIG. 3 is a side sectional view showing a first dielectric layer disposed on a substrate and a second surface??? of a die of an embodiment according to the present invention;

FIG. 4 is a side sectional view showing a second dielectric layer disposed on a first dielectric layer of an embodiment according to the present invention;

FIG. 5 is a side sectional view showing a first slot and a second slot both filled with a metal paste of an embodiment according to the present invention;

FIG. 6 is a side sectional view showing grinding of the metal paste with a level higher than a surface of a second dielectric layer in the embodiment in FIG. 5 according to the present invention;

FIG. 7 is a side sectional view showing wire bonding of an embodiment according to the present invention;

FIG. 8 is a side sectional view showing formation of a plurality of openings on an outer protective layer of an embodiment according to the present invention;

FIG. 9 is a side sectional view of a fan-out wafer-level packaging (FOWLP) unit of an embodiment according to the present invention;

FIG. 10 is a side sectional view of a fan-out wafer-level packaging (FOWLP) unit of another embodiment according to the present invention.

### DETAILED DESCRIPTION OF THE PREFERRED EMBODIMENT

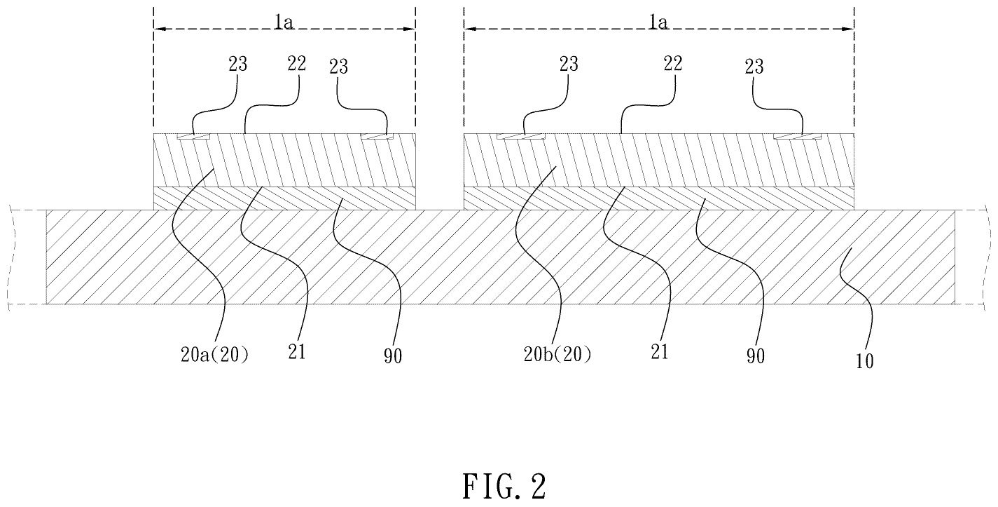

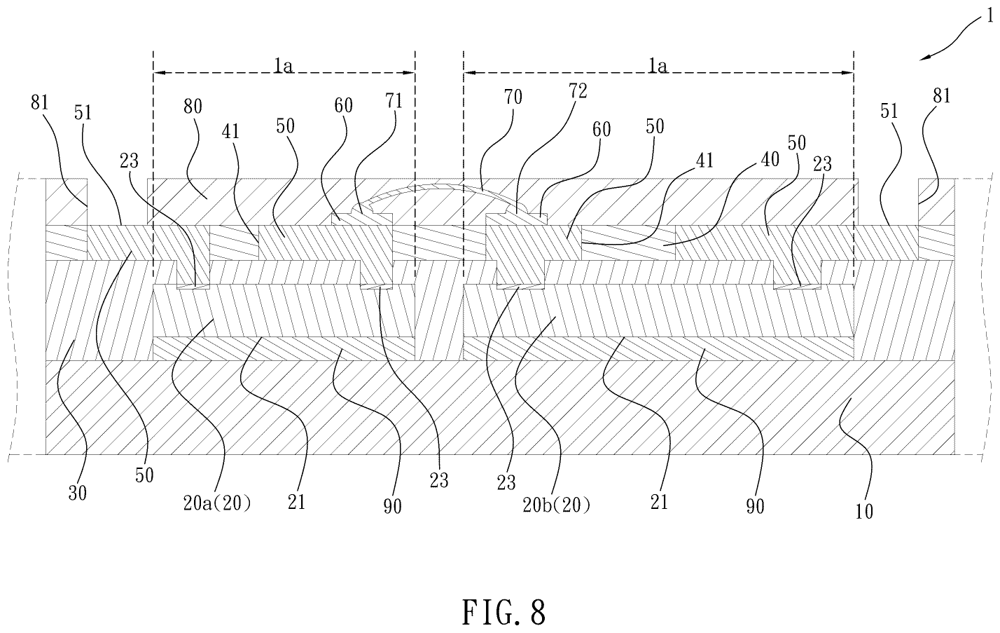

Refer to FIG. 8, a fan-out wafer-level packaging (FOWLP) unit 1 according to the present invention includes a substrate 10, at least two dies 20, a first dielectric layer 30, a second dielectric layer 40, a plurality of conductive circuits 50, at least two first bonding pads 60, at least one first bonding wire 70, and an outer protective layer 80. The substrate 10 includes silicon substrate, glass substrate, and ceramic substrate, as shown in FIG. 2.

The dies 20 are cut from the same wafer or different wafers and arranged at the substrate 10 in parallel and spaced apart from each other. Each of the dies 20 is provided with a first surface 21 and a second surface 22 opposite to the first surface 21. The first surface 21 of the die 20 is fixed on the substrate 10 while the second surface 22 of the die 20 is provided with a plurality of die pads 23. As shown in FIG. 2, an area just above the second surface 22 is defined as a chip area 1a. In FIG. 2, the number of the die pads 23 on the respective dies 20 is two and this is taken as an example.

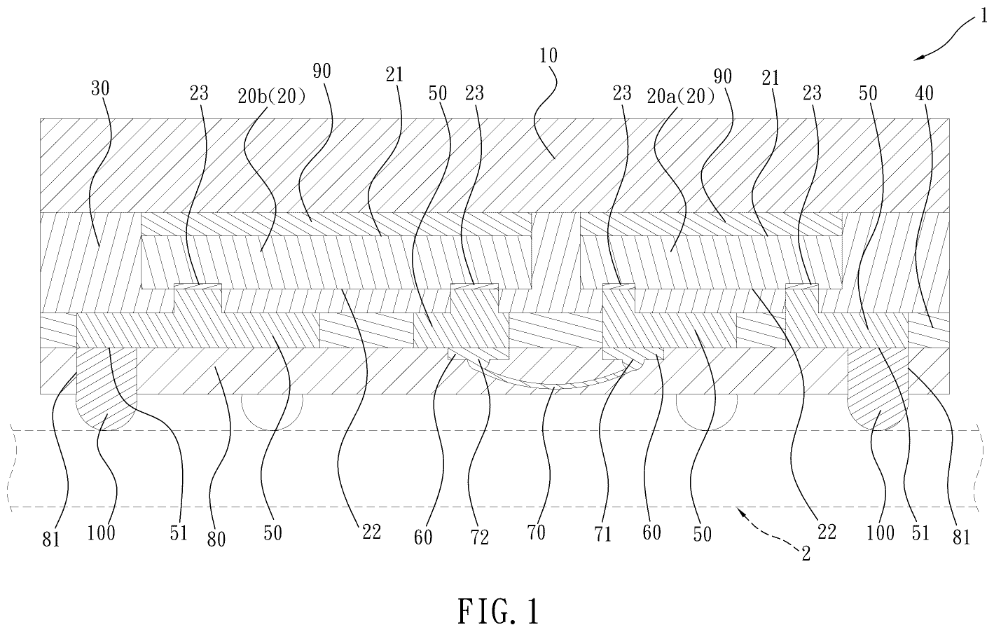

In the embodiment shown in FIG. 1-9, the dies 20 on the substrate 10 further includes a first die 20a and a second die 20b. In this embodiment, there are two dies 20 taken as an example.

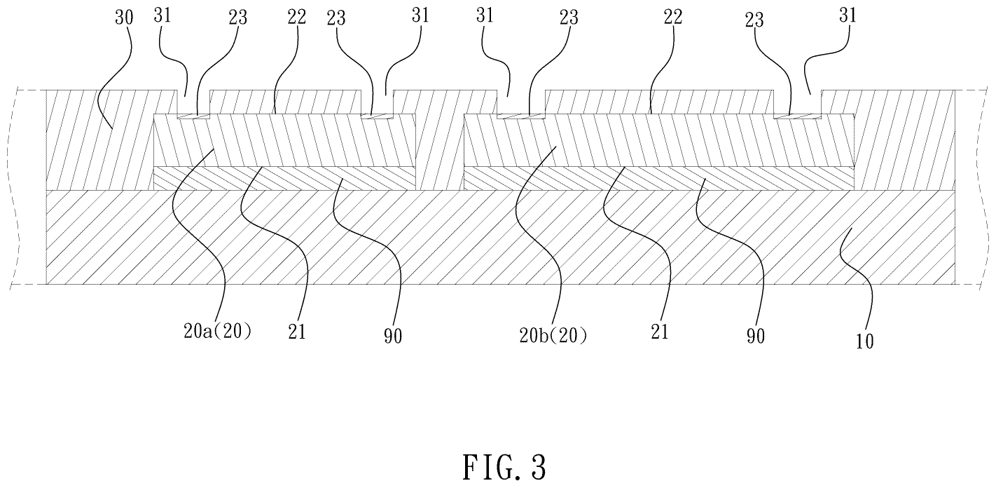

Refer to FIG. 3, the first dielectric layer 30 is mounted to the substrate 10 and the second surface 22 of the respective dies 20 (20a, 20b) and provided with a plurality of first slots 31 extending in a horizontal direction. The respective die pads 23 of the respective dies 20 (20a, 20b) are exposed through the respective first slots 31.

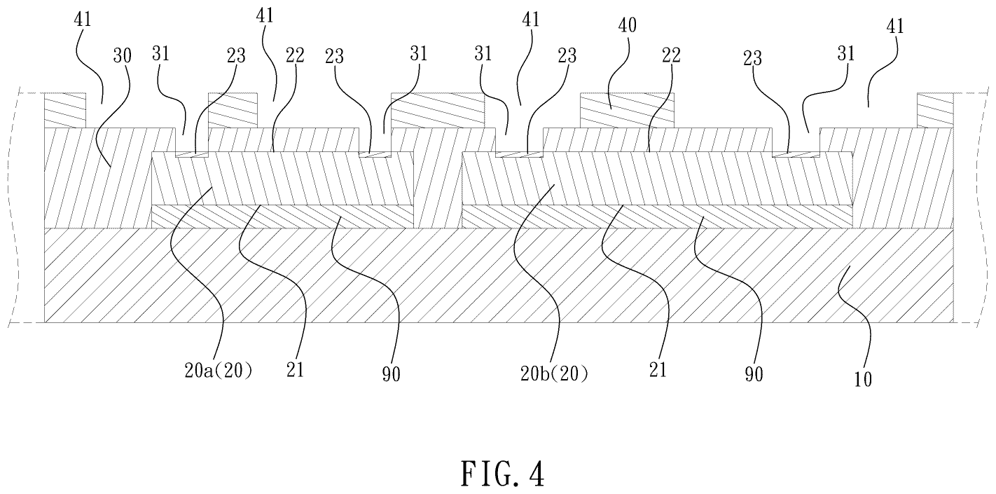

The second dielectric layer 40 is disposed over the first dielectric layer 30 and provided with a plurality of second slots 41 extending in a horizontal direction. The respective second slots 41 are communicating with the respective first slots 31, as shown in FIG. 4.

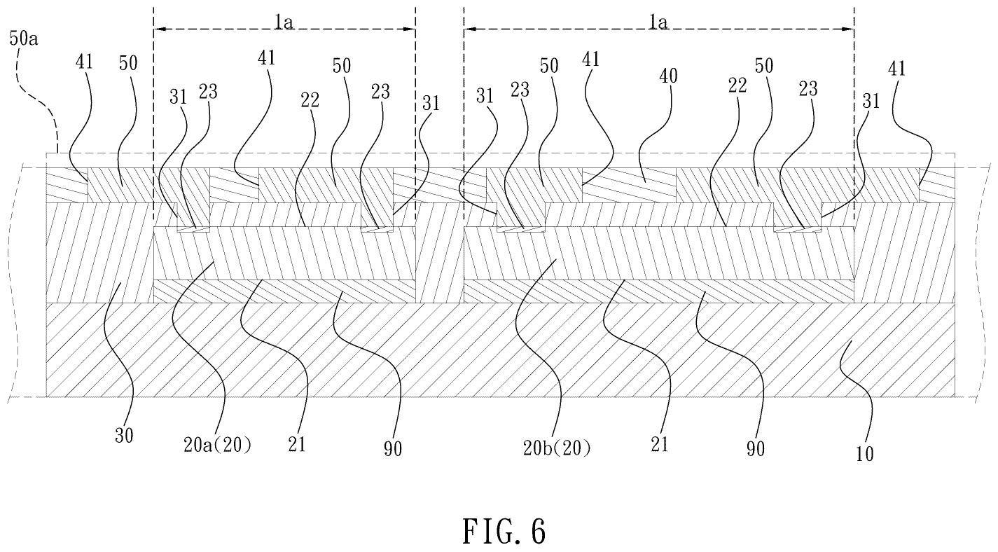

The respective conductive circuits 50 are formed by a metal paste 50a filled in the respective first slots 31 and the respective second slots 41. As shown in FIG. 6, the respective conductive circuits 50 are electrically connected with the respective die pads 23 of the respective dies 20 (20a, 20b). The metal paste 50a includes, but not limited to, silver paste, nano-scale silver paste, copper paste, and nano-scale copper paste.

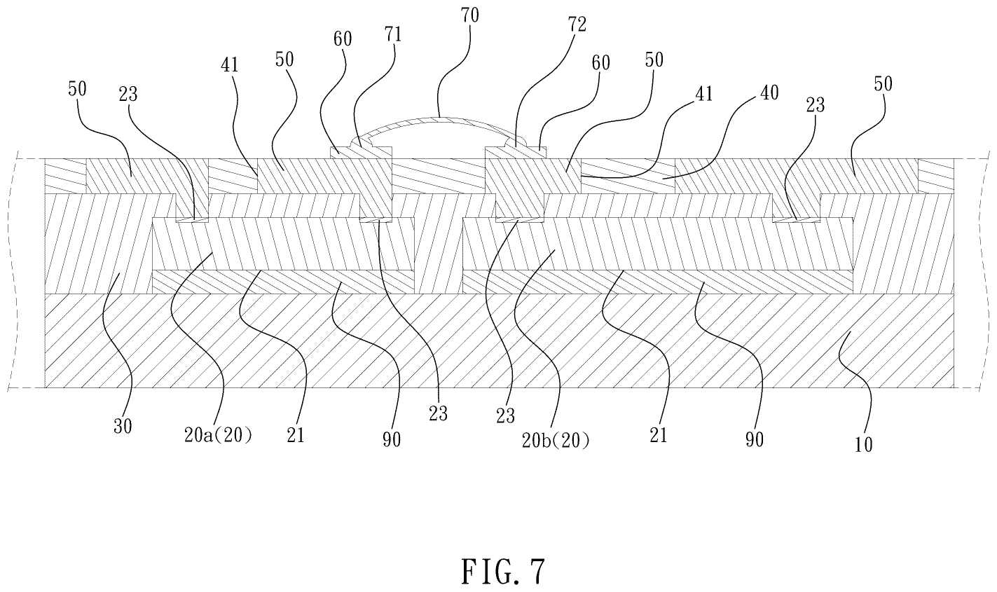

As shown in FIG. 7, the two first bonding pads 60 are formed on two of the conductive circuits 50 on the dies 20 20 (20a, 20b) correspondingly. The first bonding pad 60 withstands a positive pressure generated during wire bonding or formation of bonding points so that internal circuits will not be damaged due to the positive pressure. Thereby the internal circuits (such as the conductive circuits 50) are allowed to pass under the first bonding pads 60 or arrange under the first bonding pads 60.

The first bonding wire 70 forms a first bonding point 71 and a second bonding point 72 on the first bonding pads 61 of the dies 20 (20a, 20b) correspondingly. Thus the respective dies 20 (20a, 20b) are electrically connected by the first bonding point 71, as shown in FIG. 7.

Moreover, refer to the embodiment in FIG. 1, the bonding points on the first die 20a and the second die 20b are respectively the first bonding point 71 and the second bonding point 72. There is one bonding wire 70 used in this embodiment and taken as an example.

The outer protective layer 80 is arranged over the second dielectric layer 40 and covering the first bonding pads 60 and the first bonding wire 70. The outer protective layer 80 is provided with a plurality of openings 81 and at least two of the openings 81 are located around the chip area 1a on the second surface 22 of the respective dies 20 (20a, 20b), as shown in FIG. 8. Each of the respective conductive circuits 50 is exposed through the corresponding opening 81 to form a second bonding pad 51. The respective dies 20 (20a, 20b) are electrically connected to the outside through the respective die pads 23, the respective conductive circuits 50, and the respective second bonding pads 51 in turn. Thereby the FOWLP unit 1 is formed.

The respective dies 20 (20a, 20b) in the FOWLP unit 1 are electrically connected by the first bonding wire 70, as shown in FIG. 8.

A method of manufacturing the FOWLP unit 1 according to the present invention includes the following steps.

Step S1: providing a substrate 10, as shown in FIG. 2.

Step S2: arranging a plurality of dies 20 cut from the same wafer or different wafers on the substrate 10 in parallel and spaced from one another, as shown in FIG. 2. Each of the dies 20 includes a first surface 21 and a second surface 22 opposite to the first surface 21. The first surface 21 of the die 20 is arranged at the substrate 10 while the second surface 22 of the die 20 is provided with a plurality of die pads 23. An area just above the second surface 22 is defined as a chip area 1a.

Step S3: paving a first dielectric layer 30 over the substrate 10 and the second surface 22 of the respective dies 20, as shown in FIG. 3.

Step S4: forming a plurality of first slots 31 extending horizontally on the first dielectric layer 30 and exposing the respective die pads 21 of the respective dies 20 through the respective first slots 31, as shown in FIG. 3.

Step S5: arranging a second dielectric layer 40 over the first dielectric layer 30, as shown in FIG. 4.

Step S6: forming a plurality of second slots 41 extending horizontally on the second dielectric layer 40 and communicating the second slots 41 with the first slots 31 correspondingly, as shown in FIG. 4.

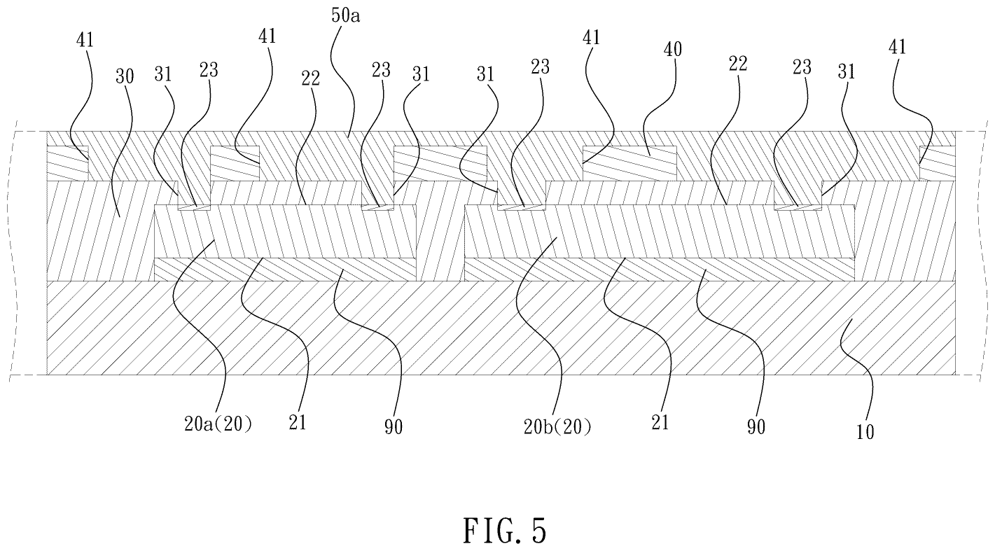

Step S7: filling a metal paste 50a into the respective first slots 31 and the respective second slots 41 and allowing a level of the metal paste 50a higher than a surface of the second dielectric layer 40, as shown in FIG. 5.

Step S8: grinding the metal paste 50a with the level higher than the surface of the second dielectric layer 40 to make a surface of the metal paste 50a flush with the surface of the second dielectric layer 40 and form a plurality of conductive circuits 50, as shown in FIG. 6.

Step S9: forming a first bonding pad 60 on the respective conductive circuits 50 in the respective dies 20 and arranging the first bonding pads 60 in a manner that the two first bonding pads 60 are disposed on the conductive circuits 50 corresponding to each other, as shown in FIG. 7.

Step S10: performing a wire bonding process for allowing at least one first bonding wire 70 to form a first bonding point 71 and a second bonding point 72 on the first bonding pads 60 of the dies 20 correspondingly, as shown in FIG. 7.

Step S11: covering the second dielectric layer 40 with an outer protective layer 80 which covers the first bonding pads 60 and the first bonding wire 70, as shown in FIG. 8.

Step S12: forming a plurality of openings 81 on the outer protective layer 80 and at least one of the openings 81 is formed around the chip area 1a on the second surface 22 of the respective dies 20 so that each of the respective conductive circuits 50 is exposed through the corresponding opening 81 to form a second bonding pad 51 in the opening 81, as shown in FIG. 8.

Step S13: performing cutting to form a plurality of fan-out wafer-level packaging (FOWLP) units 1 each of which having at least the two dies 20 packaged therein, as shown in FIG. 8.

The steps S3-S9 and the step S12 of the method of manufacturing the module 1 are considered as key steps of manufacturing the redistribution layer (RDL) of the FOWLP unit 1. The steps S4-S8 are easy to be implemented precisely so that the manufacturing process is simplified and the respective conductive circuits 50 in the RDL have electrical extension in the XY plane and interconnections. At the same time, the FOWLP unit 1 manufactured still has slim size and light weight to some degree even the FOWLP unit 1 includes at least the two dies 20.

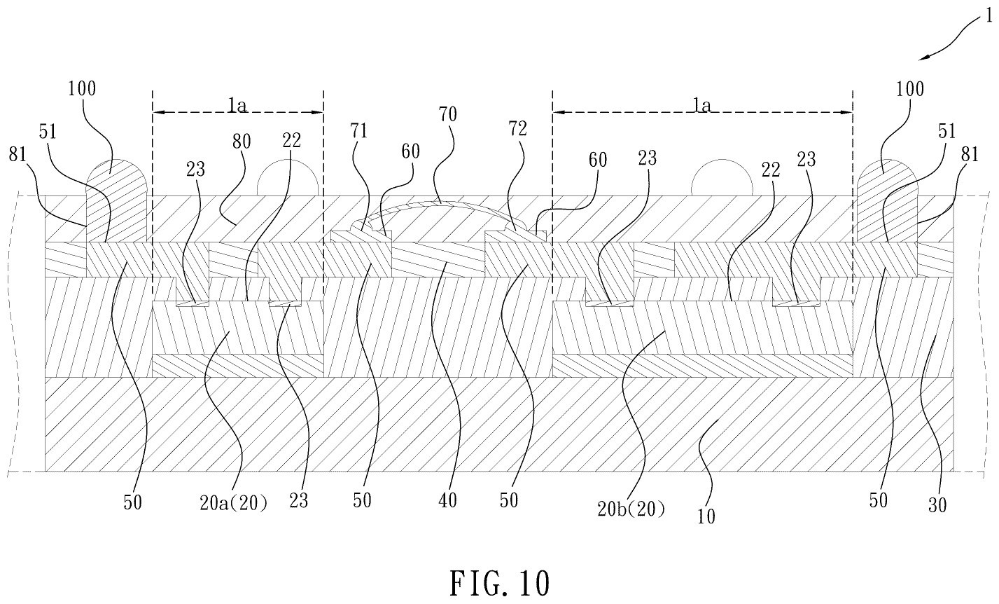

Refer to FIG. 10, the die 20 (20a, 20b) can be electrically connected to the first bonding pad 60 of another die 20 through the die pad 23, the conductive circuit 50, and the first bonding wire 70 on the corresponding first bonding pad 60 in turn. For example, the first die 20a is electrically connected to the second die 20b through the first bonding wire 70. Refer to FIG. 2, when the dies 20 are cut from the same wafers, the respective dies 20 have the same specifications, effectiveness, or functions. When the dies 20 are cut from different wafers, this helps diversified applications of the product. The respective dies 20 have different specifications, effectiveness, or functions. As shown in FIG. 2, the size of the first die 20a is smaller than the size of the second die 20b.

Refer to FIG. 2, levels of the second surfaces 22 of the respective dies 20 on the substrate 10 are the same. Thereby the first slots 31 of the first dielectric layer 30 and the second slots 41 of the second dielectric layer 40 can be extended and formed smoothly and flatly. This helps the following structures stocked over the dies 20 keep flatness and evenness in order to increase reliability of the product.

Refer to FIG. 2, the first surface 21 of the die 20 is arranged at the substrate 10 by a die attach film (DAF) 90, but not limited.

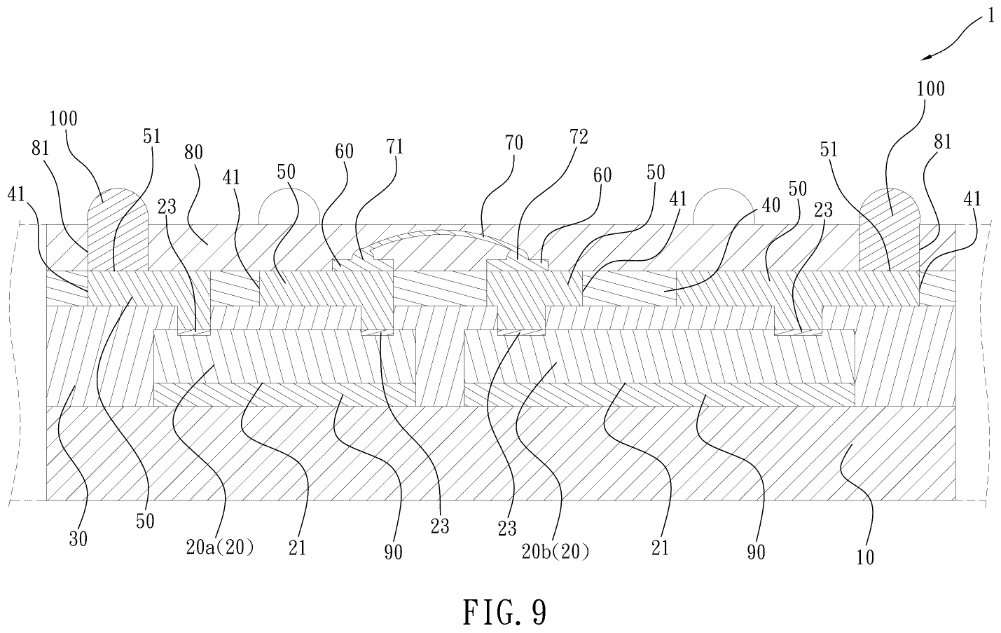

Refer to FIG. 9, a solder ball 100 is disposed on each of the openings 81 and electrically connected to the second bonding pad 51 in the opening 81. The FOWLP unit 1 can be electrically connected to and disposed on an electronic component 2 by the solder ball 100, as shown in FIG. 1. The electronic component 2 can be a printed circuit board, but not limited, as shown in FIG. 1.

Compared with the FOWLP unit available now, the present FOWLP unit 1 has the following advantages.
(1) The steps S3-S9 and S12 of the present method of manufacturing the present FOWLP unit 1 are simplified and easily-implemented steps and this is especially helpful in reduction of a thickness of the packaging unit. Thus the manufacturing process of the present invention is not only more simplified and with reduced cost, but also improving use efficiency and reliability of the FOWLP unit 1.
(2) The method of forming the conductive circuits 50 according to the present invention can effectively solve the problems of the FOWLP technology available now generated during manufacturing of the respective conductive circuits including higher manufacturing cost and less environmental benefit.
(3) The respective conductive circuits 50 in the RDL of the present invention have electrical extension in the XY plane and interconnections. At the same time, the FOWLP unit 1 manufactured still has slim size and light weight to some degree. Thereby products with better performance (for example, the respective dies 20 have the same specifications, effectiveness, or functions) or more functions (for example, the respective dies 20 have different specifications, effectiveness, or functions) are provided and their market competitiveness is improved.
(4) The die 20 of the present invention can be electrically connected to the first bonding pad 60 of another die 20 through the die pad 23, the conductive circuit 50, and the first bonding wire 70 on the corresponding first bonding pad 60 in turn. For example, the first die 20a is electrically connected to the second die 20b through the first bonding wire 70. Thereby the problem of no effective electrical connection between the dies of the multi-die type FOWLP unit available now can be solved effectively.

1. A fan-out wafer level packaging (FOWLP) unit comprising:
a substrate;
at least two dies cut from the same wafer or different wafers, arranged at the substrate in parallel and spaced apart from each other, and provided with a first surface and a second surface opposite to each other; the first surface of the die fixed on the substrate while the second surface of the die provided with a plurality of die pads and an area just above the second surface of the die is defined as a chip area;
a first dielectric layer mounted to the substrate and the second surface of the dies and provided with a plurality of first slots extending in a horizontal direction; wherein the respective die pads of the dies are exposed through the respective first slots;
a second dielectric layer is disposed over the first dielectric layer and provided with a plurality of second slots extending in a horizontal direction and communicating with the first slots;
a plurality of conductive circuits formed by a metal paste filled in the first slots and the second slots and electrically connected to the die pads of the respective dies;
at least two first bonding pads arranged in a manner that the two first bonding pads are disposed on the two conductive circuits of the die correspondingly;
at least one first bonding wire forming a first bonding point and a second bonding point on the first bonding pads correspondingly of the respective dies by a wire bonding process so that the dies are electrically connected through the first bonding wire;
an outer protective layer arranged over the second dielectric layer and covering the first bonding pads and the first bonding wire; the outer protective layer provided with a plurality of openings and at least two of the openings located around the chip area on the second surface of the respective dies; wherein each of the conductive circuits is exposed through the corresponding opening and forming a second bonding pad in the opening; wherein the dies are electrically connected to the outside through the die pads, the conductive circuits, and the second bonding pads around the chip area on the second surface of the dies in turn; thereby the FOWLP unit is formed; wherein the dies in the FOWLP are electrically connected through the first bonding wire;
wherein a method of manufacturing the FOWLP unit comprising the steps of:
Step S1: providing a substrate;
Step S2: arranging a plurality of dies cut from the same wafer or different wafers on the substrate in parallel and spaced from one another; wherein each of the dies includes a first surface and a second surface opposite to the first surface; the first surface of the die is arranged at the substrate while the second surface of the die is provided with a plurality of die pads and an area just above the second surface is defined as a chip area;
Step S3: paving a first dielectric layer over the substrate and the second surface of the respective dies;
Step S4: forming a plurality of first slots extending horizontally on the first dielectric layer and exposing the respective die pads of the respective dies through the respective first slots;
Step S5: arranging a second dielectric layer over the first dielectric layer;
Step S6: forming a plurality of second slots extending horizontally on the second dielectric layer and communicating the second slots with the first slots correspondingly;
Step S7: filling a metal paste into the respective first slots and the respective second slots and allowing a level of the metal paste higher than a surface of the second dielectric layer;
Step S8: grinding the metal paste with the level higher than the surface of the second dielectric layer to make a surface of the metal paste flush with the surface of the second dielectric layer and form a plurality of conductive circuits;
Step S9: forming a first bonding pad on the respective conductive circuits in the respective dies and arranging the first bonding pads in a manner that the two first bonding pads are disposed on the conductive circuits corresponding to each other;
Step S10: performing wire bonding for allowing at least one first bonding wire to form a first bonding point and a second bonding point on the first bonding pads of the dies correspondingly; wherein the dies are electrically connected by the first bonding wire;
Step S11: covering the second dielectric layer with an outer protective layer which covers the first bonding pads and the first bonding wire;
Step S12: forming a plurality of openings on the outer protective layer and at least one of the openings is located around the chip area on the second surface of the respective dies so that each of the respective conductive circuits is exposed through the corresponding opening to form a second bonding pad in the opening; and
Step S13: performing cutting to form a plurality of fan-out wafer-level packaging (FOWLP) units.

2. The FOWLP unit as claimed in claim 1, wherein the die is electrically connected to the first bonding pad of another die through the die pad, the conductive circuit, and the first bonding wire on the first bonding pad located around the chip area on the second surface of the respective dies in turn.

3. The FOWLP unit as claimed in claim 1, wherein the dies are cut from the same wafer or different wafers.

4. The FOWLP unit as claimed in claim 1, wherein levels of the second surfaces of the respective dies on the substrate are the same.

5. The FOWLP unit as claimed in claim 1, wherein the substrate includes silicon substrate, glass substrate, and ceramic substrate.

6. The FOWLP unit as claimed in claim 1, wherein the metal paste includes silver paste, nano-scale silver paste, copper paste, and nano-scale copper paste.

7. The FOWLP unit as claimed in claim 1, wherein the first surface of the die is disposed on the substrate by a die attach film (DAF).

8. The FOWLP unit as claimed in claim 1, wherein each of the openings is provided with a solder ball which is electrically connected to the second bonding pad in the opening.

9. The FOWLP unit as claimed in claim 8, wherein the FOWLP unit is electrically connected to and disposed on an electronic component by the solder balls.
